(19) United States
(12) Patent Application Publication
(10) Pub. No.: US 2025/0372411 A1
(43) Pub. Date: Dec. 4, 2025

(54) SUBSTRATE PROCESSING APPARATUS AND RECORDING MEDIA

(71) Applicant: EBARA CORPORATION, Tokyo (JP)

(72) Inventor: KUNIMASA MATSUSHITA, Tokyo (JP)

(73) Assignee: EBARA CORPORATION, Tokyo (JP)

(21) Appl. No.: 19/216,740

(22) Filed: May 23, 2025

(30) Foreign Application Priority Data
May 30, 2024 (JP) 2024-087891

(51) Int. Cl. H01L 21/67

(52) U.S. Cl. CPC H01L 21/67034; H01L 21/67092; H01L 21/67219

(57) ABSTRACT

To appropriately control the supply amount of a rinse liquid, or to calculate the supply amount of the rinse liquid.

A substrate processing apparatus includes: a first processing unit which processes a substrate; a second processing unit which processes the substrate after being processed by the first processing unit; a rinse liquid supply mechanism which supplies a rinse liquid to the substrate in standby after being processed by the first processing unit and before being processed by the second processing unit; and a control part which controls at least one of a supply amount per unit time of the rinse liquid, time for supplying the rinse liquid, and standby time until the substrate is transported to the second processing unit, so that a supply amount of the rinse liquid supplied from the rinse liquid supply mechanism to the substrate is within a target range.

### CROSS-REFERENCE TO RELATED APPLICATION

This application claims the priority benefits of Japanese application no. 2024-087891, filed on May 30, 2024. The entirety of the above-mentioned patent application is hereby incorporated by reference herein and made a part of this specification.

### BACKGROUND

### Technical Field

The disclosure relates to a substrate processing apparatus, a recording medium recording a program for controlling supply of a rinse liquid, and a recording medium recording a program for calculating a supply amount of a rinse liquid.

### Description of Related Art

Patent Literature 1 (Japanese Patent Application Laid-Open No. 2018-160614) discloses a substrate processing apparatus including a drying prevention fluid supply means that supplies a drying prevention fluid to a substrate surface to prevent drying of a processing liquid on the substrate surface while the substrate is transported by a transport means.

The disclosure is to appropriately control the supply amount of the rinse liquid, or to calculate the supply amount of the rinse liquid.

### SUMMARY

By way of illustration, the following solution means are provided.

[1]

A substrate processing apparatus includes:
a first processing unit which processes a substrate;
a second processing unit which processes the substrate after being processed by the first processing unit;
a rinse liquid supply mechanism which supplies the rinse liquid to the substrate in standby after being processed by the first processing unit and before being processed by the second processing unit; and
a control part which controls at least one of a supply amount d per unit time of the rinse liquid, time for supplying the rinse liquid, and standby time t0 until the substrate is transported to the second processing unit, so that a supply amount of the rinse liquid supplied from the rinse liquid supply mechanism to the substrate is within a target range.
   [2]

In the substrate processing apparatus according to [1],
the supply amount d per unit time of the rinse liquid and the standby time t0 are given, and
the control part controls the time for supplying the rinse liquid.
   [3]

In the substrate processing apparatus according to [2],
the rinse liquid supply mechanism includes a valve that switches whether or not to supply the rinse liquid, and
the control part controls the time for supplying the rinse liquid by controlling opening and closing of the valve.
   [4]

In the substrate processing apparatus according to [3],
the target range is determined by a minimum supply amount Lmin and a maximum supply amount Lmax, and
the control part
   opens the valve if d*t0<Lmax,
   opens the valve until time t-Lmin/d elapses if Lmax<d*t0, and then intermittently switches opening and closing of the valve until the standby time t0 elapses.
      [5]

A substrate processing apparatus, includes:
a first processing unit which processes a substrate;
a second processing unit which processes the substrate after being processed by the first processing unit;
one or more rinse liquid supply mechanisms which supply a rinse liquid to the substrate in standby after being processed by the first processing unit and before being processed by the second processing unit; and
a control part which calculates a supply amount of the rinse liquid supplied from the rinse liquid supply mechanism to the substrate, based on a supply amount per unit time of the rinse liquid and time for supplying the rinse liquid.
   [6]

In the substrate processing apparatus according to [5], the control part issues an alarm based on a comparison between a calculated amount of the rinse liquid and a first target value.

[7]

The substrate processing apparatus according to [5] or [6]
includes two or more of the rinse liquid supply mechanisms, and
the control part calculates a total amount of the rinse liquid supplied by the two or more rinse liquid supply mechanisms from a start of a polishing process for the substrate until an end of a washing process.
   [8]

In the substrate processing apparatus according to [7], the control part issues an alarm based on a comparison between the calculated total amount of the rinse liquid and a second target value.

[9]

The substrate processing apparatus according to any one of [1] to [8]
includes a transport unit which transports the substrate after being processed by the first processing unit to the second processing unit, and
the rinse liquid supply mechanism supplies the rinse liquid to the substrate on the transport unit.
   [10]

The substrate processing apparatus according to any one of [1] to [9],
includes a mounting table, on which the substrate is mounted after being processed by the first processing unit and before being processed by the second processing unit, and
the rinse liquid supply mechanism supplies the rinse liquid to the substrate mounted on the mounting table.
   [11]

In the substrate processing apparatus according to any one of [1] to [10],
the first processing unit and the second processing unit are both polishing units,
the first processing unit is a polishing unit and the second processing unit is a washing unit, or
the first processing unit and the second processing unit are both washing units.
   [12]

A method for controlling supply of a rinse liquid controls at least one of a supply amount per unit time of the rinse liquid, time for supplying the rinse liquid, and standby time until a substrate is transported to a second processing unit, so that a supply amount of the rinse liquid supplied from a rinse liquid supply mechanism to the substrate, which is in standby after being processed by a first processing unit and before being processed by the second processing unit, is within a target range.

[13]

A method for calculating a supply amount of a rinse liquid calculates a supply amount of a rinse liquid supplied from a rinse liquid supply mechanism to a substrate, which is in standby after being processed by a first processing unit and before being processed by a second processing unit, based on a supply amount per unit time of the rinse liquid and time for supplying the rinse liquid.

[14]

A recording medium recording a program for controlling supply of a rinse liquid causes a computer to function as a control part that controls at least one of a supply amount per unit time of the rinse liquid, time for supplying the rinse liquid, and standby time until a substrate is transported to a second processing unit, so that a supply amount of the rinse liquid supplied from a rinse liquid supply mechanism, which supplies the rinse liquid to the substrate in standby after being processed by a first processing unit and before being processed by the second processing unit, to the substrate is within a target range.

[15]

A recording medium recording a program for calculating a supply amount of a rinse liquid causes a computer to function as a control part that calculates a supply amount of a rinse liquid supplied to a substrate from a rinse liquid supply mechanism, which supplies the rinse liquid to the substrate in standby after being processed by a first processing unit and before being processed by a second processing unit, based on a supply amount per unit time of the rinse liquid and time for supplying the rinse liquid.

### BRIEF DESCRIPTION OF THE DRAWINGS

FIG. 1 is a schematic configuration diagram of a substrate processing apparatus 100.

FIG. 2 is a diagram describing an example of the transport path of a substrate W.

FIG. 3 is a diagram schematically showing a rinse liquid supply mechanism 10a which supplies a rinse liquid to the substrate W transported by a transport unit 6b.

FIG. 4 is a diagram schematically showing a rinse liquid supply mechanism 10b which supplies a rinse liquid to the substrate W mounted on a mounting table 7a.

FIG. 5 is a flowchart showing an example of the processing operation of a control part 8.

FIG. 6 is a flowchart showing another example of the processing operation of the control part 8.

FIG. 7 is a flowchart showing yet another example of the processing operation of the control part 8.

### DESCRIPTION OF THE EMBODIMENTS

The supply amount of the rinse liquid can be appropriately controlled. Alternatively, the supply amount of the rinse liquid can be calculated.

Hereinafter, embodiments according to the disclosure are described in detail with reference to the drawings.

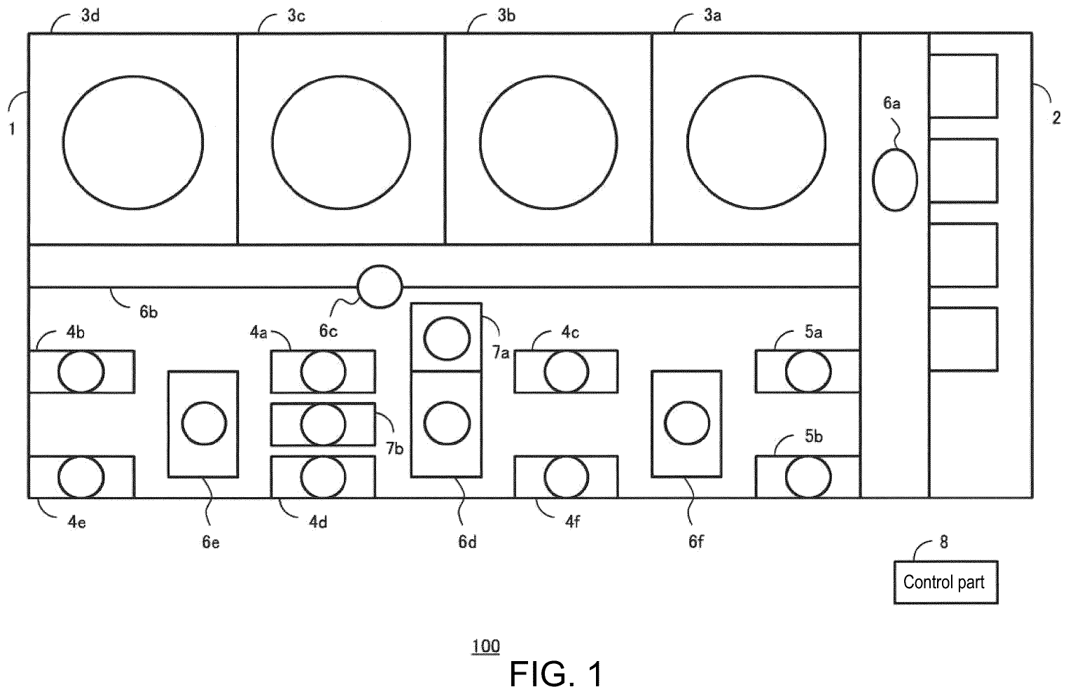

FIG. 1 is a schematic configuration diagram of a substrate processing apparatus 100. The substrate processing apparatus 100 is, for example, a CMP apparatus, and includes a housing 1 having a substantially rectangular shape, and a load port 2 disposed close to the housing 1.

A substrate cassette (not illustrated) that stocks multiple substrates W is mounted on the load port 2. The substrate W can be, for example, a semiconductor wafer. However, the substrate W to be processed is not limited to a semiconductor wafer, and may also be another type of substrate used in the manufacturing of a semiconductor apparatus, such as a glass substrate, a ceramic substrate, etc. Further, on at least one surface of the substrate W, a device including a semiconductor film, a metal film (for example, copper), etc., is formed.

The substrate processing apparatus 100 includes one or more (four in FIG. 1) polishing units 3a to 3d (which may be collectively referred to as a “polishing unit 3” in the case of not particularly distinguishing them), one or more (six in FIG. 1) washing units 4a to 4f (which may be collectively referred to as a “washing unit 4” in the case of not particularly distinguishing them), one or more (two in FIG. 1) drying units 5a and 5b (which may be collectively referred to as a “drying unit 5” in the case of not particularly distinguishing them), one or more (six in FIG. 1) transport units 6a to 6f (which may be collectively referred to as a “transport unit 6” in the case of not particularly distinguishing them), and one or more (two in FIG. 1) mounting tables 7a and 7f (which may be collectively referred to as a “mounting table 7” in the case of not particularly distinguishing them), and the aforementioned are disposed inside the housing 1.

Further, the substrate processing apparatus 100 includes a control part 8 that controls the polishing unit 3, the washing unit 4, the drying unit 5, and the transport unit 6. The control part 8 is, for example, a computer having memory and a processor. Each of processes described later is executed by the processor executing a program stored in the memory.

The polishing unit 3 polishes the surface of the substrate W. More specifically, the polishing unit 3 polishes the surface of the substrate W by supplying slurry onto the substrate W while rotating the substrate W, and pressing a polishing member (not illustrated) against the surface of the substrate W. Polishing debris or slurry can remain on the substrate W after polishing.

The washing unit 4 washes the surface of the substrate W after polishing. More specifically, the washing unit 4 washes the surface of the substrate W by pressing a substrate washing tool (not illustrated in FIG. 1) against the surface of the substrate W while rotating the substrate W.

The drying unit 5 dries the surface of the substrate W after washing. For example, the drying unit 5 is a spin drying apparatus, and injects isopropyl alcohol vapor from a nozzle onto the rotating substrate W to dry the substrate W, while rotating the substrate W at high speed to dry the substrate W by centrifugal force.

Hereinafter, the polishing unit 3, the washing unit 4, and the drying unit 5 may be collectively referred to as a “processing unit”. That is, the term “processing unit” simply used refers to any one of the polishing unit 3, the washing unit 4, and the drying unit 5.

The transport unit 6 is configured to transport the substrate W; for example, the transport unit 6 transports the substrate W after processing by a certain processing unit to the next processing unit. The substrate W located on the transport unit 6 can be said to be in a standby state. Specific examples of the transport unit 6 are as follows.

The transport unit 6a is disposed close to the load port 2, the transport unit 6b, and the drying units 5a and 5b. The transport unit 6a performs actions such as receiving the substrate W before processing from the load port 2 and transferring the substrate W before processing to the transport unit 6b, receiving the substrate W after processing from the transport unit 6b, and receiving the substrate W from the drying units 5a and 5b.

The transport unit 6b extends in a longitudinal direction in a central part of the housing 1. The transport unit 6b may be a linear transporter that moves in the longitudinal direction of the housing 1. The transport unit 6b transports the substrate W between the transport unit 6a, the polishing units 3a to 3d, and the transport unit 6c.

The transport unit 6c is disposed close to the transport unit 6b and the mounting table 7a. The transport unit 6c may be a swing transporter that performs rotational movement around a predetermined vertical axis. The transport unit 6c transports the substrate W between the transport unit 6b and the mounting table 7a.

The transport unit 6d is disposed close to the washing units 4a, 4c, 4d, and 4f and the mounting tables 7a and 7b. The transport unit 6d may be a robot. The transport unit 6d transports the substrate W between the washing units 4a, 4c, 4d, and 4f and the mounting tables 7a and 7b.

The transport unit 6e is disposed close to the washing units 4a, 4b, 4d and 4e and the mounting table 7b. The transport unit 6e may be a robot. The transport unit 6e transports the substrate W between the washing units 4a, 4c, 4d, and 4f and the mounting table 7b.

The transport unit 6f is disposed close to the washing units 4c and 4f and the drying units 5a and 5b. The transport unit 6f may be a robot. The transport unit 6f transports the substrate W between the washing units 4c and 4f and the drying units 5a and 5b.

On the mounting table 7, the substrate W is mounted after being processed by a certain processing unit and before being processed by the next processing unit. The substrate W mounted on the mounting table 7 can be said to be in a standby state. As an example, the mounting table 7a is disposed close to the transport units 6c and 6d. The mounting table 7b is disposed close to the transport units 6d and 6e.

Note that the disposition of the polishing unit 3, the washing unit 4, the drying unit 5, the transport unit 6, and the mounting table 7 is merely an example. One or more transport units 6 may be provided that can transport the substrate W in the order of the polishing unit 3, the washing unit 4, and the drying unit 5. Further, the mounting table 7 may be provided at needed positions as needed, and may be omitted if unneeded.

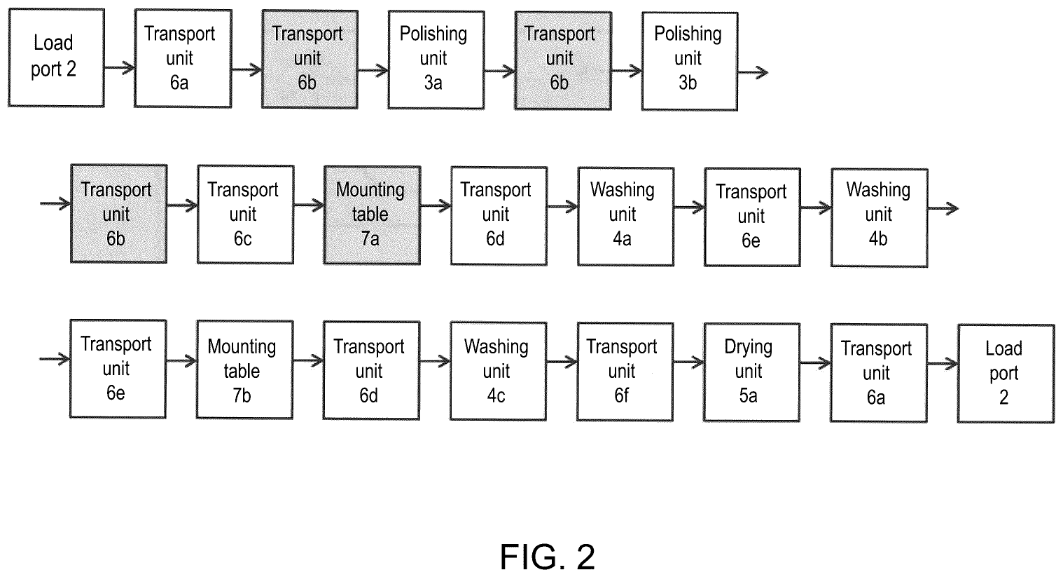

FIG. 2 is a diagram that describes an example of the transport path of the substrate W. The substrate W is transported from the load port 2 to the transport unit 6b by the transport unit 6a. Next, the substrate W is transported from the transport unit 6b to the polishing unit 3a. In the polishing unit 3a, the substrate W is polished. The polished substrate W is transported from the polishing unit 3a to the polishing unit 3b by the transport unit 6b. In the polishing unit 3b, the substrate W is polished.

The polished substrate W is transported from the polishing unit 3b to the transport unit 6c by the transport unit 6b, and is mounted onto the mounting table 7a. Next, the substrate Wis transported from the mounting table 7a to the washing unit 4a by the transport unit 6d. In the washing unit 4a, the substrate W is washed. The washed substrate W is transported from the washing unit 4a to the washing unit 4b by the transport unit 6e. In the washing unit 4b, the substrate W is washed.

The washed substrate W is transported from the washing unit 4b by the transport unit 6e, and is mounted onto the mounting table 7b. Next, the substrate W is transported from the mounting table 7b by the transport unit 6d, and is transported to the washing unit 4c. In the washing unit 4c, the substrate W is washed. The washed substrate W is transported from the washing unit 4c to the drying unit 5a by the transport unit 6f. In the drying unit 5a, the substrate W is dried. The dried substrate W is transported to the load port 2 by the transport unit 6a.

Here, because processing based on a predetermined recipe is performed in each of processing units, a predetermined amount of a rinse liquid based on the recipe is supplied.

However, the substrate W is not necessarily processed in the next processing unit immediately after being processed in a certain processing unit, and may enter a standby state between processing units (for example, on the transport unit 6 or on the mounting table 7) in which processing is not performed. The period of the standby state (standby period) is not constant, and may be long or short.

In the case of not supplying the rinse liquid during the standby period, the substrate W may dry out. On the other hand, in the case of continuing to supply the rinse liquid during the standby period, devices (particularly, metal films such as copper) formed on the substrate W may corrode. Furthermore, fluctuations in the amount of the supplied rinse liquid depending on the length of the standby period may also affect the yield.

Therefore, in the embodiment, the supply amount of the rinse liquid during the standby period is controlled. As a configuration for the purpose, the substrate processing apparatus 100 includes one or more rinse liquid supply mechanisms 10 that supply the rinse liquid (for example, pure water or chemical liquid) to the substrate W in standby after being processed by one processing unit and before being processed by another processing unit (not shown in FIG. 1).

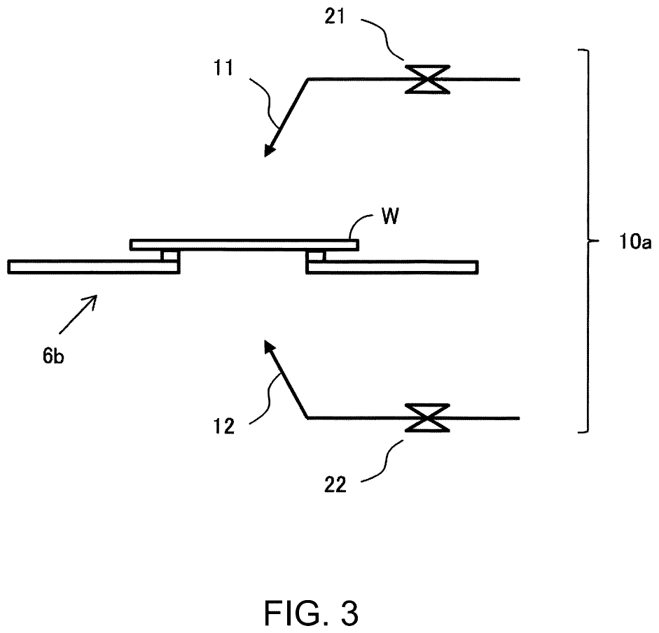

As an example, as shown in FIG. 3, a rinse liquid supply mechanism 10a which supplies a rinse liquid to the substrate W transported by the transport unit 6b is provided. The rinse liquid supply mechanism 10a has nozzles 11 and 12 and valves 21 and 22 (supply control means). In the case of the valve 21 opening, a rinse liquid is supplied from the nozzle 11 to the upper surface of the substrate W. In the case of the valve 22 opening, a rinse liquid is supplied from the nozzle 12 to the lower surface of the substrate W. Opening and closing of the valve 21 and the valve 22 is controlled by the control part 8.

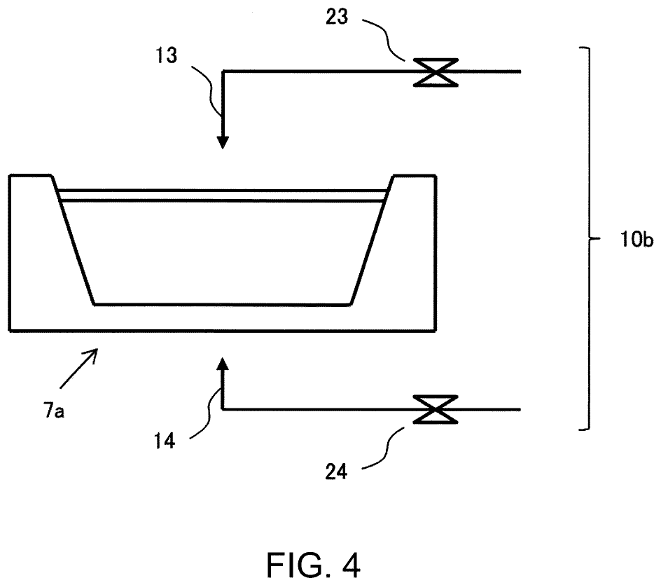

Furthermore, as shown in FIG. 4, a rinse liquid supply mechanism 10b which supplies a rinse liquid to the substrate W mounted on the mounting table 7a may be provided. The rinse liquid supply mechanism 10b has nozzles 13 and 14 and valves 23 and 24 (supply control means). In the case of the valve 23 opening, a rinse liquid is supplied from the nozzle 13 to the upper surface of the substrate W. In the case of the valve 24 opening, a rinse liquid is supplied from the nozzle 14 to the lower surface of the substrate W. Opening and closing of the valve 23 and the valve 24 is controlled by the control part 8.

Furthermore, a rinse liquid supply mechanism 10 which supplies the rinse liquid to the substrate W transported by other transport units 6 or the substrate W mounted on the mounting table 7 may be provided.

And, the control part 8 performs control such that the supply amount of the rinse liquid supplied from the rinse liquid supply mechanism 10 to the substrate W is within a target range. As a specific example, the control part 8 controls the supply time of the rinse liquid by controlling opening and closing of the valves 21 to 24. As another example, the control part 8 controls the supply amount per unit time of the rinse liquid. As yet another example, the control part 8 may control the time until the substrate W is transported to the next processing unit (hereinafter referred to as “standby time”).

In the following example, a supply amount d per unit time of the rinse liquid is a given constant value, and is not subject to control. Furthermore, standby time t0 also is a given value determined from the recipe of the processing unit, and is not subject to control.

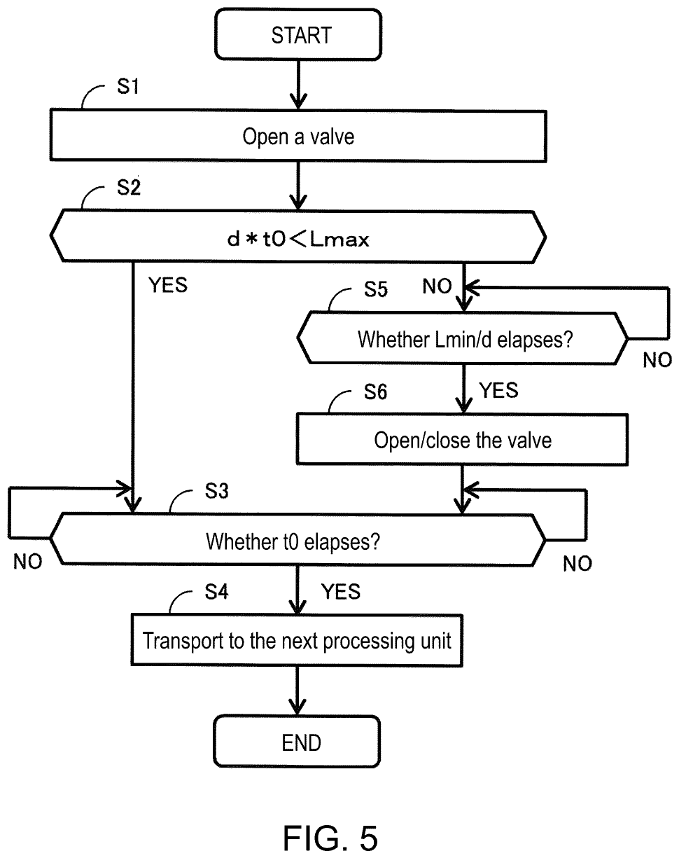

FIG. 5 is a flowchart showing an example of the processing operation of the control part 8. Hereinafter, the rinse liquid supply mechanism 10a shown in FIG. 3 will be described as an example, but the disclosure can also be applied to other rinse liquid supply mechanisms 10. Furthermore, it is assumed that the target range of the rinse liquid supply amount is Lmin to Lmax, and is set in the control part 8 in advance.

In order to supply the rinse liquid to the substrate W which is received by the transport unit 6b and is in a standby state, the control part 8 opens the valves 21 and 22 (step S1). In this way, the rinse liquid is supplied to the substrate W.

Here, the control part 8 determines whether or not the following Formula (1) is satisfied (step S2).

d*t0<Lmax (1)

In the case where Formula (1) is satisfied (YES in step S2), even if the rinse liquid is continuously supplied during the standby time t0, the supply amount of the rinse liquid does not exceed the upper limit value Lmax of the target range. Therefore, the control part 8 continues the supply of the rinse liquid without closing the valves 21 and 22. Then, in response to the standby time t0 elapsing (YES in step S3), the control part 8 closes the valves 21 and 22 as needed, and controls the transport unit 6b to transport the substrate W to the next processing unit (step S4).

On the other hand, in the case where Formula (1) is not satisfied (NO in step S2), if the rinse liquid is continuously supplied during the standby time t0, the supply amount of the rinse liquid exceeds the upper limit value Lmax of the target range. Therefore, the control part 8 keeps the valves 21 and 22 open until t=Lmin/d elapses (NO in step S5). As a result, the rinse liquid of the lower limit value Lmin or more is supplied. Then, after t=Lmin/d elapses, the control part 8 intermittently switches the opening and closing of the valves 21 and 22 (step S6). As a result, the risk that the rinse liquid is excessively supplied can be reduced while preventing drying of the substrate W. Thereafter, in response to the standby time t0 elapsing (YES in step S3), the control part 8 closes the valves 21 and 22 as needed, and controls the transport unit 6b to transport the substrate W to the next processing unit (step S4).

Additionally, in step S3, in the case where transport to the next processing unit is unable to be performed due to unexpected trouble etc. even if the standby time t0 calculated from the recipe of the processing unit elapses, the supply of the rinse liquid may be continued prioritizing drying prevention, or the supply of the rinse liquid may be stopped prioritizing corrosion prevention. Furthermore, by setting Lmin=Lmax=0 to the control part 8, configuration may also be made so that the rinse liquid is not supplied.

In this way, by controlling the supply amount of the rinse liquid, defects such as corrosion of the metal film in the substrate W can be reduced, and the yield can be improved.

The above is an example in which the control part 8 controls the supply amount of the rinse liquid, but the amount of the rinse liquid actually supplied may also be calculated and an alarm may also be issued as needed.

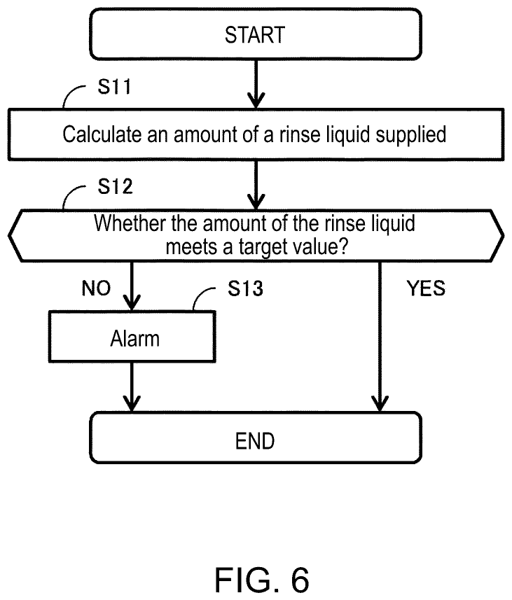

FIG. 6 is a flowchart showing another example of the processing operation of the control part 8. In the example, an alarm is issued based on the amount of the rinse liquid supplied during a single standby between a certain processing unit and the next processing unit.

The control part 8 calculates the amount of the rinse liquid supplied to the substrate W during standby (step S11). As a specific example, the control part 8 can calculate the supply amount of the rinse liquid based on the supply amount d per unit time of the rinse liquid and time t for which the rinse liquid has been supplied. The time t for which the rinse liquid has been supplied is, for example, the time during which the valves 21 and 22 of the rinse liquid supply mechanism 10a are ON.

The calculated supply amount of the rinse liquid may be stored as a processing log. By storing the supply amount of the rinse liquid for multiple substrates W, the supply amount can be utilized as statistical data. As an example, from the average value or standard deviation of the supply amount of the rinse liquid, an abnormal substrate W of which supply amount of the rinse liquid deviates from the normal can be identified. Alternatively, the optimal supply amount of the rinse liquid can be automatically calculated, and such a supply amount of the rinse liquid can be reflected in the above-described upper limit value Lmax and lower limit value Lmin.

Then, the control part 8 compares the calculated supply amount of the rinse liquid with a preset target value (step S12). The target value may be a lower limit value, an upper limit value, or both a lower limit value and an upper limit value. In the case of the target value not being satisfied, the control part 8 issues an alarm (step S13).

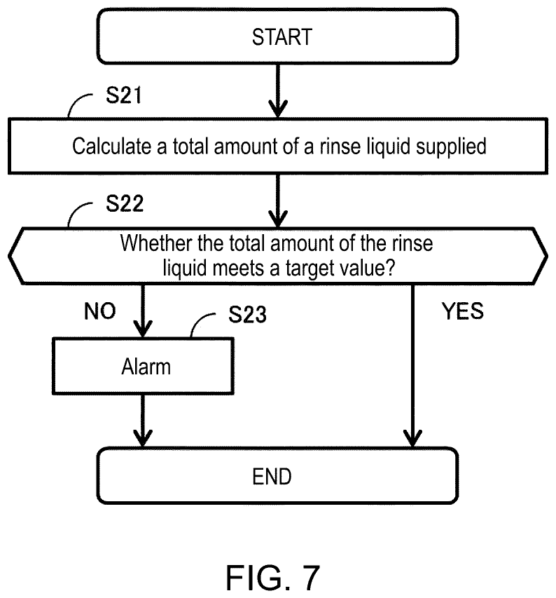

FIG. 7 is a flowchart showing another example of the processing operation of the control part 8. In the example, an alarm is issued based on the total amount of the rinse liquid supplied during all standby periods from the first processing unit to the last processing unit.

By adding the supply amount of the rinse liquid in each of the standby periods calculated in step S11 described in FIG. 6, the control part 8 calculates the total amount of the rinse liquid supplied from the rinse liquid supply mechanism 10 from the start of the polishing process by the polishing unit 3 for the substrate W until the end of the washing process by the washing unit 4 (step S21). The calculated total supply amount of the rinse liquid may be stored as a processing log.

For example, in the case of the substrate processing apparatus 100 including two rinse liquid supply mechanisms 10a and 10b, the supply amounts of rinse liquids by both of the rinse liquid supply mechanisms 10a and 10b are added together. As shown in FIG. 2, in the case of the substrate W entering a standby state three times on the transport unit 6b and entering a standby state once on the mounting table 7a, the supply amounts of the rinse liquid for the three instances from the rinse liquid supply mechanism 10a shown in FIG. 3 and the supply amount of the rinse liquid for the one instance from the rinse liquid supply mechanism 10b shown in FIG. 4 are added together.

Then, the control part 8 compares the calculated total supply amount of the rinse liquid with a preset target value (step S22). The target value may be a lower limit value, an upper limit value, or both a lower limit value and an upper limit value. In the case of the target value not being satisfied, the control part 8 issues an alarm (step S23).

Thus, by calculating the supply amount of the rinse liquid, the possibility of defects, such as corrosion of the metal film on the substrate W may be detected.

Any part or all of each of the functional parts described in the specification may be realized by a program. The program mentioned in the specification can be non-transitorily recorded on a computer-readable recording medium.

Such a program may be one installed on a computer (a so-called native application). In that case, the program may be downloaded to the computer via a communication line such as the Internet (including wireless communication), or may be distributed in a state installed on the computer.

Alternatively, the program may be one that operates on a web browser (a so-called web application). In that case, the computer may receive the program described in a markup language file (for example, an HTML file) from a server, and the program may be executed by the web browser.

Based on the description above, a person skilled in the art may conceive additional effects or various modified examples of the disclosure, but aspects of the disclosure are not limited to the individual embodiments described above. For example, inventions extracting merely a part of each of the embodiments or inventions combining multiple embodiments are naturally conceivable. Various additions, modifications, and partial deletions may be made without departing from the conceptual idea and spirit of the disclosure derived from the content defined in the scope of the claims and equivalents thereof.

For example, what is described as one apparatus (or member, the same applies hereinafter) in the specification (including what is depicted as one apparatus in the drawings) may be realized by multiple apparatuses. Conversely, what is described as multiple apparatuses in the specification (including what is depicted as multiple apparatuses in the drawings) may be realized by one apparatus. Alternatively, a part or all of the means or functions described as being included in a certain apparatus may be included in another apparatus.

Furthermore, not all of the features described in the specification are needed requirements. In particular, any feature described in the specification but not included in the scope of the claims may be considered as optional additional features.

Furthermore, the term “means” in the specification and the scope of the claims, unless otherwise specified, itself means hardware (or functions realized by the hardware), and does not include humans (or human mental activities).

Furthermore, functions realized by components described in the specification may be implemented in circuitry or processing circuitry programmed to realize the described functions, including a general-purpose processor, a special-purpose processor, an integrated circuit, Application Specific Integrated Circuits (ASICs), a Central Processing Unit (CPU), conventional circuits, and/or combinations thereof. The processor includes transistors and other circuits, and is considered circuitry or processing circuitry. The processor may be a programmed processor that executes a program stored in memory.

Furthermore, in the specification, circuitry, units, and means are hardware programmed to realize the described functions, or hardware that executes the functions. The hardware may be any hardware disclosed in the specification, or any hardware programmed to realize the described functions, or any hardware known to execute the functions.

In the case where the hardware is a processor considered to be a type of circuitry, the circuitry, means, or unit is a combination of hardware and software used to configure the hardware and/or processor.

Note that the above embodiments are merely used to illustrate the technical solutions of the disclosure, but not to limit the technical solutions of the disclosure. Although the disclosure has been described in detail with reference to the foregoing embodiments, those of ordinary skill in the art should understand that the technical solutions described in the foregoing embodiments may still be modified, or some or all of the technical features thereof may be equivalently replaced without departing from the spirit and the scope of the disclosure.

What is claimed is:

1. A substrate processing apparatus, comprising:
a first processing unit, processing a substrate;
a second processing unit, processing the substrate after being processed by the first processing unit;
a rinse liquid supply mechanism, supplying a rinse liquid to the substrate in standby after being processed by the first processing unit and before being processed by the second processing unit; and
a control part, controlling at least one of a supply amount d per unit time of the rinse liquid, time for supplying the rinse liquid, and standby time t0 until the substrate is transported to the second processing unit, so that a supply amount of the rinse liquid supplied from the rinse liquid supply mechanism to the substrate is within a target range.

2. The substrate processing apparatus according to claim 1, wherein
the supply amount d per unit time of the rinse liquid and the standby time t0 are given, and
the control part controls the time for supplying the rinse liquid.

3. The substrate processing apparatus according to claim 2, wherein
the rinse liquid supply mechanism comprises a valve that switches whether or not to supply the rinse liquid, and
the control part controls the time for supplying the rinse liquid by controlling opening and closing of the valve.

4. The substrate processing apparatus according to claim 3, wherein
the target range is determined by a minimum supply amount Lmin and a maximum supply amount Lmax, and
the control part
opens the valve if d*t0<Lmax,
opens the valve until time t=Lmin/d elapses if Lmax<d*t0, and then intermittently switches opening and closing of the valve until the standby time t0 elapses.

5. A substrate processing apparatus, comprising:
a first processing unit, processing a substrate;
a second processing unit, processing the substrate after being processed by the first processing unit;
one or more rinse liquid supply mechanisms, supplying a rinse liquid to the substrate in standby after being processed by the first processing unit and before being processed by the second processing unit; and
a control part, calculating a supply amount of the rinse liquid supplied from the rinse liquid supply mechanism to the substrate, based on a supply amount per unit time of the rinse liquid and time for supplying the rinse liquid.

6. The substrate processing apparatus according to claim 5, wherein the control part issues an alarm based on a comparison between a calculated amount of the rinse liquid and a first target value.

7. The substrate processing apparatus according to claim 5,
comprising two or more of the rinse liquid supply mechanisms, and
the control part calculating a total amount of the rinse liquid supplied by the two or more rinse liquid supply mechanisms from a start of a polishing process for the substrate until an end of a washing process.

8. The substrate processing apparatus according to claim 7, wherein the control part issues an alarm based on a comparison between the calculated total amount of the rinse liquid and a second target value.

9. The substrate processing apparatus according to claim 1,
comprising a transport unit, transporting the substrate after being processed by the first processing unit to the second processing unit, and
the rinse liquid supply mechanism supplying the rinse liquid to the substrate on the transport unit.

10. The substrate processing apparatus according to claim 1,
comprising a mounting table, on which the substrate is mounted after being processed by the first processing unit and before being processed by the second processing unit, and
the rinse liquid supply mechanism supplying the rinse liquid to the substrate mounted on the mounting table.

11. The substrate processing apparatus according to claim 1, wherein
the first processing unit and the second processing unit are both polishing units,
the first processing unit is a polishing unit and the second processing unit is a washing unit, or
the first processing unit and the second processing unit are both washing units.

12. A recording medium recording a program for controlling supply of a rinse liquid, causing a computer to function as a control part that controls at least one of a supply amount per unit time of the rinse liquid, time for supplying the rinse liquid, and standby time until a substrate is transported to a second processing unit, so that a supply amount of the rinse liquid supplied from a rinse liquid supply mechanism, which supplies the rinse liquid to the substrate in standby after being processed by a first processing unit and before being processed by the second processing unit, to the substrate is within a target range.

13. A recording medium recording a program for calculating a supply amount of a rinse liquid, causing a computer to function as a control part that calculates a supply amount of a rinse liquid supplied to a substrate from a rinse liquid supply mechanism, which supplies the rinse liquid to the substrate in standby after being processed by a first processing unit and before being processed by a second processing unit, based on a supply amount per unit time of the rinse liquid and time for supplying the rinse liquid.
